(19) United States
(12) Patent Application Publication
(10) Pub. No.: US 2005/0276910 A1
(43) Pub. Date: Dec. 15, 2005

(54) Post processing of films to improve film quality

(75) Inventor: Rahul Gupta, Milpitas, CA (US)

Correspondence Address: Siemens Corporation;Attn: Elsa Keller, Legal Administrator, Intellectual Property Department, 170 Wood Avenue South, Iselin, NJ, 08830, US

(73) Assignee: Osram Opto Semiconductors GmbH

(21) Appl. No.: 10/865,552

(22) Filed: Jun. 9, 2004

(51) Int. Cl. B05D 5/12

(52) U.S. Cl. 427/66

(57) ABSTRACT

An organic material is deposited on a lower electrode layer of an organic electronic device prior to fabrication of organic layers. The organic material is allowed to dry into a film. The device is subjected to post-processing at a high temperature and/or high humidity environment to induce reflow of the film. When the film dries again, the resulting film is flatter and more uniform in profile.

### BACKGROUND

1. Field of the Invention

This invention relates generally to the art of thin film device processing and fabrication. More specifically, the invention relates to the fabrication of Organic Light Emitting Diode based displays and other electronic devices which use selective deposition.

2. Related Art

Display and lighting systems based on LEDs (Light Emitting Diodes) have a variety of applications. Such display and lighting systems are designed by arranging a plurality of opto-electronic elements (“elements”) such as arrays of individual LEDs. LEDs that are based upon semiconductor technology have traditionally used inorganic materials, but recently, the organic LED (“OLED”) has come into vogue for certain applications. Examples of other elements/devices using organic materials include organic solar cells, organic transistors, organic detectors, and organic lasers. There are also a number of biotechnology applications such as biochips for DNA recognition, combinatorial synthesis, etc. which utilize organic materials.

An OLED is typically comprised of two or more thin at least partially conducting organic layers (e.g., an electrically conducting hole transporting polymer layer (HTLS) and an emissive polymer layer where the emissive polymer layer emits light) which are sandwiched between an anode and a cathode. Under an applied forward potential, the anode injects holes into the conducting polymer layer, while the cathode injects electrons into the emissive polymer layer. The injected holes and electrons each migrate toward the oppositely charged electrode and recombine to form an exciton in the emissive polymer layer. The exciton relaxes to a lower energy state by emission of radiation and in process, emits light.

Other organic electronic devices, such as organic transistors and organic sensors will also typically contain a conducting organic (polymer) layer and other organic layers. A number of these OLEDs or other organic electronic devices can be arranged in a pattern over a substrate as for instance in display system. One way of patterning organic electronic devices over a substrate is to create pockets by photo-lithography and then utilize a process known as ink-jet printing. The use of a photo-resist layer to define pockets for inkjet printing is disclosed in published patent application Number U.S. 2002/0060518 A1 entitled “Organic Electroluminescent Device and Method of Manufacturing Thereof”. In ink-jet printing, polymer or organic solution is deposited by discharging droplets of the solution into the pockets from a print head. One common application of inkjet printing is the patterning of multi-color OLED pixels (such as RGB patterned pixels) in order to manufacture a color display.

Inkjet printing is one of among many selective deposition techniques. Other known techniques include flexographic printing, screen printing, etc. The film which results from the drying of solution can often be non-uniform in thickness (i.e. not flat). In the case of OLEDs, non-uniformity in the profile of the film can affect device performance.

Photoresists are also used to pattern displays and electronic devices made using traditional spin coating techniques. Even in spin coated devices, the presence of the photoresist results in non-uniform film deposition.

As can be observed in FIG. 1, the drying pattern is very non-uniform and shows a piling up on the edges of the drop 200 which represents a drop of a conducting polymer solution. This is due to the difference in the rate of evaporation at different regions of drop 200, resulting in surface tension variations which in turn causes the substance to move towards the edges of the drop 200 from the middle, and hence the ultimate deposition of more of the substance at the edges and in the middle. This phenomenon is usually referred to as the Marangoni effect.

When there are normal sloping photo-resist banks as in the case of drop 210, there is still substantial non-uniformity in the profile of the drop 210 when dried. There is accumulation at the edges which affects the useful part of the device. At a fixed applied voltage, as the thickness of the dried film increases, the current through the film decreases leading to less light being emitted. If the thickness of the film is not uniform, more current flows through the thinner parts of the film than through the thicker parts of the film. Thus more light is emitted through the thinner part of the film and less or no light is emitted through the thicker parts of the film. This would leave less of the film that is actually usable in terms of acceptable device performance as shown.

FIG. 2 illustrates a patterned organic electronic device with a plurality of deposited organic films. Each of the films 280 was produced by depositing organic solution in discrete regions between photo-resist lines. As is apparent, the films 280 do not have a uniform thickness over their width. The darkened colors in each film shows accumulation at the center of the films. There is also poor contact with the edges of the photo-resist lines and hence, the potential for poor device performance as these areas can act as low resistance paths and result in high leakage currents.

It would be thus desirable to provide more uniform films as well as remove such defects as poor wetting of the edges and pinholes.

### BRIEF DESCRIPTION OF THE DRAWINGS

FIG. 1 illustrates the drying pattern of a liquid substance when the substance is dropped with and without photo-resist.

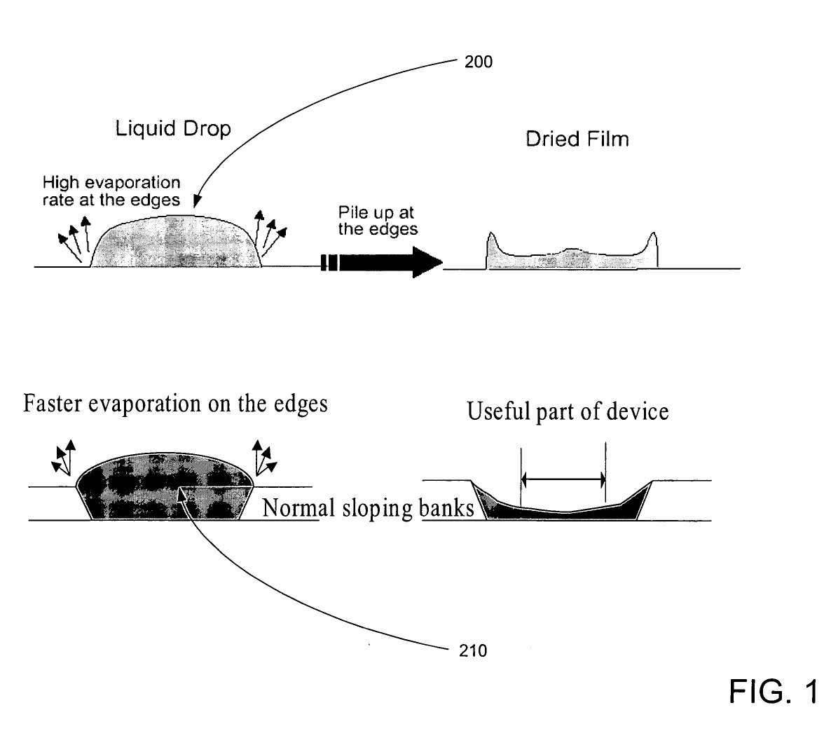

FIG. 2 illustrates a patterned organic electronic device with a plurality of deposited organic films.

FIGS. 3(a)-(b) illustrates the profile of a polymer film when the film is subjected to post-processing in accordance with the invention.

FIG. 4 shows a cross-sectional view of an embodiment of an organic electronic device 405 according to the invention.

FIG. 5 shows a workflow of fabricating an OLED using post-processing of conducting polymer film in accordance with the invention.

FIGS. 6(a) and 6(b) illustrate improved coverage of the substrate that leads to a reduction of pinhole defects and incomplete filling of the material in the desired region as well as improved contact/adhesion of the film to the features on the substrate when utilizing one or more embodiments of the invention.

### DETAILED DESCRIPTION OF THE INVENTION

In accordance with the invention, the drying profile of a deposited organic (e.g. conducting polymer) solution is modified by post-processing the dried film in a high temperature and/or high humidity post-processing environment. The post-processing induces a “reflow” of the organic material to fill in any defects and thereby creates a more uniform and flatter film profile. “Reflow” may be defined as the redistribution of material on the deposition surface i.e. the substrate. The post-processing is performed prior to baking or other film hardening processes which are typically used to permanently fix the geometry and positioning of the film for stability purposes. The post-processing for reflow is also performed prior to the addition of any other layers on top of the deposited layer. The post-processing environment may be an environmentally controlled glove-box or similar chamber.

Post-processing conditions include the time of exposure as well as the level of humidity and the temperature. The optimum levels of humidity and temperature will be dependent upon factors such as the chemical and physical properties of the material under reflow, the time needed to attain stability of the condition(s) in the post-processing environment, and so on, and can be determined by experimentation. After reflow, the resulting film is more uniform in thickness, particularly in the active area of the film (the middle portion). In one embodiment of the invention, a post-processing which exposes a dried conducting polymer film to a humidity of 95% and a temperature of 85C causes a reflow of the film which dries to a more uniform profile. Post-processing can be used on any type of films whether deposited by selective deposition techniques such as inkjet printing or non-selective deposition techniques such as spin coating. Any of the post-processing conditions can be modified as needed depending upon the application in which the polymer films are used. In addition, the temperature may be held to room temperature and only the humidity varied, or the humidity held to normal conditions with the temperature varied. The time of exposure to post-processing may also involve the time required to attain the desired condition level in the post-processing environment.

In some embodiments of the invention, a process of fabricating an organic electronic device is disclosed whereby an organic solution is deposited upon an existing deposition surface, allowed to dry and then post-processed to induce reflow. The organic solution is allowed to evaporate and dry into a layer of film which has a substantially flat and uniform profile. After the drying of this organic layer, other steps are carried out to complete the organic electronic device fabrication. Examples of such fabricated organic electronic devices include OLEDs, organic transistors, organic solar cells and so on.

In one embodiment of the invention where the organic electronic device being manufactured is an OLED, the organic solution is a conductive polymer solution which can formed from, for example, polyethylenedioxythiophene (“PEDOT”) and polystyrenesulfonic acid (“PSS”) (hereinafter “PEDOT:PSS solution”). For a bottom emitting OLED device, the deposition surface would be the surface of an anode layer such as that composed of ITO (Indium Tin-Oxide). Examples of PEDOT and other organic solutions and deposition surfaces are discussed below.

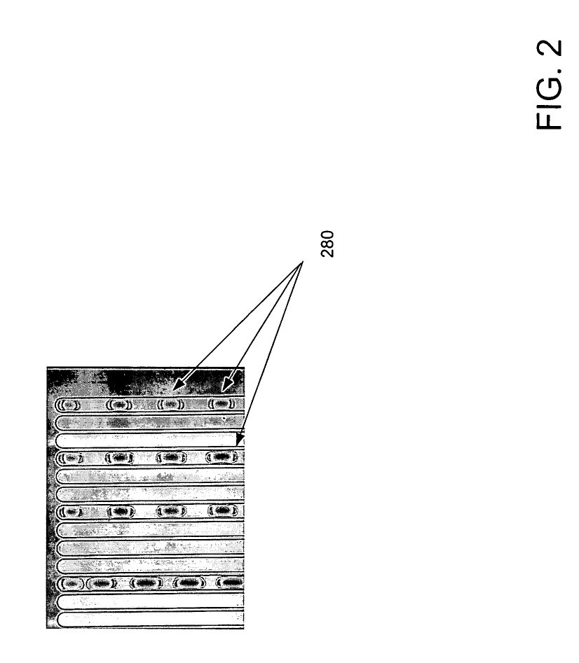

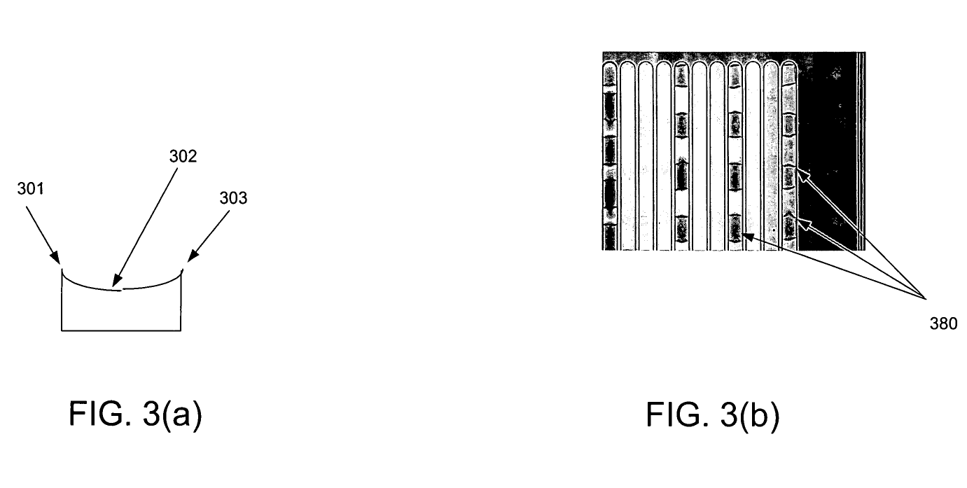

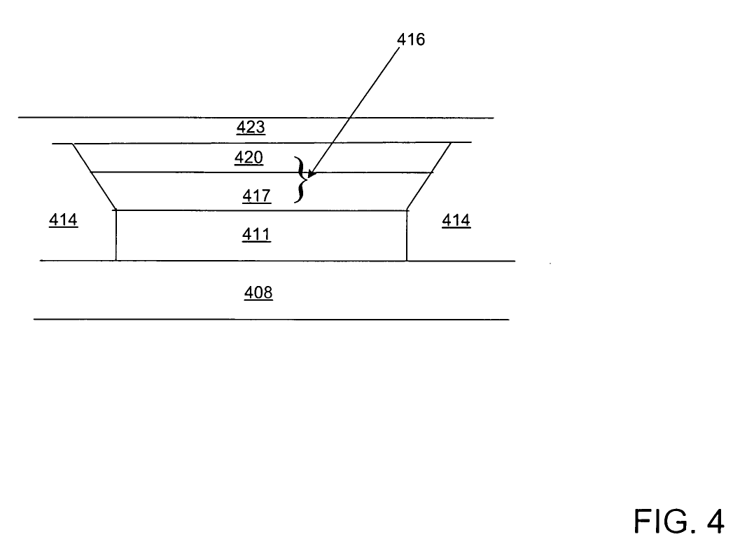

FIGS. 3(a)-(b) illustrates the profile of a polymer film when the film is subjected to post-processing in accordance with the invention. FIG. 3(a) illustrates a side-profile of the final film resulting from post-processing a single organic film. An organic solution was deposited onto a deposition surface as shown. After the film was allowed to dry, the film was exposed to a high temperature and high humidity environment. The reflow of film under these conditions is evidenced by the middle 302 and edge portions (301 and 303) being closer in thickness than with conventional deposition and drying. The composition of the film and thicknesses along the width of the film at each of the two edges 301, 303 and middle 302 is given below with respect to the FIG. 4 description. FIG. 3(b) illustrates a patterned organic electronic device with a plurality of deposited organic films fabricated in accordance with at least one embodiment of the invention. Each of the films 380 was produced by inkjet printing organic solution in discrete regions between photo-resist lines. After the initial deposition of organic solution, the resulting film was allowed to dry in air. Afterwards, the device was exposed to a high temperature, high humidity environment for a specified period of time. The films 380 soften and absorb water from the environment and then reflow. The films 380 are allowed to dry again after this reflow. As is apparent, there is more uniformity of thickness of the post-processed dried films 380 than with films 280 shown in FIG. 2.

FIG. 4 shows a cross-sectional view of an embodiment of an organic electronic device 405 according to the invention. As shown in FIG. 4, the organic electronic device 405 includes a first electrode 411 on a substrate 408. As used within the specification and the claims, the term “on” includes when layers are in physical contact and when layers are separated by one or more intervening layers. The first electrode 411 may be patterned for pixilated applications or unpatterned for backlight applications. If the electronic device 405 is a transistor, then the first electrode may be, for example, the source and drain contacts of that transistor. A photo-resist material is deposited on the first electrode 411 and patterned to form a bank structure 414 having an aperture that exposes the first electrode 411. The aperture may be a pocket (e.g., a pixel of an OLED display) or a line. The bank structure 414 is an insulating structure that electrically isolates one pocket from another pocket or one line from another line.

One or more organic materials is deposited into the aperture to form one or more organic layers of an organic stack 416. The organic stack 416 is on the first electrode 411. The organic stack 416 includes a hole transporting (conducting polymer) layer (“HTL”) 417 and other active organic layer 420. If the first electrode 411 is an anode, then the HTL 417 is on the first electrode 411. Alternatively, if the first electrode 411 is a cathode, then the active electronic layer 420 is on the first electrode 411, and the HTL 417 is on the active electronic layer 420. The electronic device 405 also includes a second electrode 423 on the organic stack 416. If the electronic device 405 is a transistor, then the second electrode 423 may be, for example, the gate contact of that transistor. Other layers than that shown in FIG. 4 may also be added including insulating layers between the first electrode 411 and the organic stack 416, and/or between the organic stack 416 and the second electrode 423. Some of these layers, in accordance with the invention, are described in greater detail below.

Substrate 408:

The substrate 408 can be any material that can support the organic and metallic layers on it. The substrate 408 can be transparent or opaque (e.g., the opaque substrate is used in top-emitting devices). By modifying or filtering the wavelength of light which can pass through the substrate 408, the color of light emitted by the device can be changed. The substrate 408 can be comprised of glass, quartz, silicon, plastic, or stainless steel; preferably, the substrate 408 is comprised of thin, flexible glass. The preferred thickness of the substrate 408 depends on the material used and on the application of the device. The substrate 408 can be in the form of a sheet or continuous film. The continuous film can be used, for example, for roll-to-roll manufacturing processes which are particularly suited for plastic, metal, and metallized plastic foils. The substrate can also have transistors or other switching elements built in to control the operation of the device.

First Electrode 411:

In one configuration, the first electrode 411 functions as an anode (the anode is a conductive layer which serves as a hole-injecting layer and which comprises a material with work function greater than about 4.5 eV). Typical anode materials include metals (such as platinum, gold, palladium, indium, and the like); metal oxides (such as lead oxide, tin oxide, ITO, and the like); graphite; doped inorganic semiconductors (such as silicon, germanium, gallium arsenide, and the like); and doped conducting polymers (such as polyaniline, polypyrrole, polythiophene, and the like).

The first electrode 411 can be transparent, semi-transparent, or opaque to the wavelength of light generated within the device. The thickness of the first electrode 411 is from about 10 nm to about 1000 nm, preferably, from about 50 nm to about 200 nm, and more preferably, is about 100 nm. The first electrode layer 411 can typically be fabricated using any of the techniques known in the art for deposition of thin films, including, for example, vacuum evaporation, sputtering, electron beam deposition, or chemical vapor deposition.

In an alternative configuration, the first electrode layer 411 functions as a cathode (the cathode is a conductive layer which serves as an electron-injecting layer and which comprises a material with a low work function). The cathode, rather than the anode, is deposited on the substrate 408 in the case of, for example, a top-emitting OLED. Typical cathode materials are listed below in the section for the “second electrode 423”.

Bank Structure 414:

The bank structure 414 is made of a photo-resist material such as, for example, polyimides or polysiloxanes. The photo-resist material can be either positive photo-resist material or negative photo-resist material. The bank structure 414 is an insulating structure that electrically isolates one pocket from another pocket or one line from another line. The bank structure 414 has an aperture 415 that exposes the first electrode 411. The aperture 415 may represent a pocket or a line. The bank structure 414 is patterned by applying lithography techniques to the photo-resist material, or by using screen printing or flexo-printing to deposit the bank material in the desired pattern. As shown in FIG. 4, the bank structure 414 can have, for example, a trapezoidal configuration in which the angle between the side wall of the bank structure 414 and the first electrode 411 is an obtuse angle. Alternatively, the bank structure can be semicircular or curved in nature.

HTL 417:

The HTL 417 has a much higher hole mobility than electron mobility and is used to effectively transport holes from the first electrode 411 to the substantially uniform organic polymer layer 420. The HTL 417 is made of polymers or small molecule materials. For example, the HTL 417 can be made of tertiary amine or carbazole derivatives both in their small molecule or their polymer form, conducting polyaniline (“PANI”), or PEDOT:PSS. The HTL 417 has a thickness from about 5 nm to about 1000 nm, preferably from about 20 nm to about 500 nm, and more preferably from about 50 to about 250 nm.

The HTL 417 functions as: (1) a buffer to provide a good bond to the substrate; and/or (2) a hole injection layer to promote hole injection; and/or (3) a hole transport layer to promote hole transport.

The HTL 417 can be deposited using selective deposition techniques or nonselective deposition techniques. Examples of selective deposition techniques include, for example, ink jet printing, flex printing, and screen printing. Examples of nonselective deposition techniques include, for example, spin coating, dip coating, web coating, and spray coating. If printing techniques are used, then the hole transporting material is deposited on the first electrode 411 and then allowed to dry into a film. The dried material represents the hole transport layer.

As mentioned above, in accordance with the invention, the dried HTL film is subjected to a post-processing. The post-processing involves placing the device under fabrication into a high temperature, high humidity environment. The temperature and humidity should be high enough to cause the HTL film to reflow. After reflow, the newly constituted material is again allowed to dry into a film. One example of a typical HTL material is PEDOT:PSS solution such as Baytron P available from H.C. Starck. The post-processing and reflow yields a dried HTL 417 film which is more uniform and flat in profile than is typically the case. The invention can serve to provide a flat and uniform drying profile of any PEDOT:PSS solution or any organic solution through the process of reflow. The specifications of acceptable flatness profiles will depend upon the application and desired design constraints. The flatness of the film can be defined by a thickness variation of y% over at least x% of the width of the HTL 417.

In one embodiment of the invention, a PEDOT solution was ink jetted over an ITO first electrode 411 and dried in air and then exposed for thirty minutes in an environment containing 95% humidity at a temperature of 85C. Three experiments were performed by varying the drop-pitch (the distance between one drop and the next on a patterned display) of the deposited solution. The height (profile) or thickness of the film was observed in three locations, left edge, middle and right edge, which the edges being defined by the interface between photo-resist and the film. The same experiments were performed on 1) conventional inkjet printing of PEDOT over ITO/glass substrate and 2) on the same samples after post-processing the sample for thirty minutes in 95% humidity at a temperature of 85C. The “drop-pitch” refers to the distance between one deposition and the next, with each deposition yielding a PEDOT film lined in a column on the ITO. The average results for the PEDOT film at different drop-pitches are shown in the following tables:

Conventional with no post-processing

| drop-pitch (μm) | left edge (nm) | middle (nm) | right edge (nm) |
|---|---|---|---|
| 40 | 250 | 450 | 250 |
| 120 | 45 | 220 | 35 |
| 240 | 30 | 130 | 35 |

Post-processing at 95% humidity and 85 C.

| drop-pitch (μm) | left edge (nm) | middle (nm) | right edge (nm) |
|---|---|---|---|
| 40 | 330 | 300 | 330 |
| 120 | 150 | 120 | 145 |
| 240 | 100 | 55 | 95 |

As evident from the above tables, at a drop-pitch 40 um there is a less than 10% difference in film thickness between middle and film edges when post-processing according to at least one embodiment of the invention is applied. At the same drop-pitch of 40 um, there is an over 44% variation in thicknesses when no post-processing is applied as is conventional practice. At all of the different drop-pitchs used, an improvement in film thickness uniformity was observable. The post-processed film has a shape similar to that illustrated in FIG. 3(a), where the left edge in the above table corresponds with left edge 301, the right edge with edge 303, and the middle with middle 302.

Active Electronic Layer 420:

Active electronic layer 420 can include one or more layers. Active electronic layer 420 includes an active electronic material. Active electronic materials can include a single active electronic material, a combination of active electronic materials, or multiple layers of single or combined active electronic materials. Preferably, at least one active electronic material is organic.

For organic LEDs (OLEDs), the active electronic layer 316 contains at least one organic material that emits light. These organic light emitting materials generally fall into two categories. The first category of OLEDs, referred to as polymeric light emitting diodes, or PLEDs, utilize polymers as part of active electronic layer 420. The polymers may be organic or organometallic in nature. As used herein, the term organic also includes organometallic materials. Preferably, these polymers are solvated in an organic solvent, such as toluene or xylene, and spun (spin-coated) onto the device, although other methods are possible. Devices utilizing polymeric active electronic materials in active electronic layer 316 are especially preferred. In addition to materials that emit light, active electronic layer 420 may include a light responsive material that changes its electrical properties in response to the absorption of light. Light responsive materials are often used in detectors and solar panels that convert light energy to electrical energy.

If the organic electronic device is an OLED or an organic laser, then the organic polymers are electroluminescent (“EL”) polymers that emit light. The light emitting organic polymers can be, for example, EL polymers having a conjugated repeating unit, in particular EL polymers in which neighboring repeating units are bonded in a conjugated manner, such as polythiophenes, polyphenylenes, polythiophenevinylenes, or poly-p-phenylenevinylenes or their families, copolymers, derivatives, or mixtures thereof. More specifically, the organic polymers can be, for example: polyfluorenes; poly-p-phenylenevinylenes that emit white, red, blue, yellow, or green light and are 2-, or 2, 5-substituted poly-p-pheneylenevinylenes; polyspiro polymers; LUMATION polymers that emit green, red, blue, or white light and are produced by Dow Chemical, Midland Mich.; or their families, copolymers, derivatives, or mixtures thereof.

If the organic electronic device is an organic solar cell or an organic light detector, then the organic polymers are light responsive material that changes its electrical properties in response to the absorption of light. The light responsive material converts light energy to electrical energy.

If the organic electronic device is an organic transistor, then the organic polymers can be, for example, polymeric and/or oligomeric semiconductors. The polymeric semiconductor can comprise, for example, polythiophene, poly(3-alkyl)thiophene, polythienylenevinylene, poly(para-phenylenevinylene), or polyfluorenes or their families, copolymers, derivatives, or mixtures thereof.

In addition to polymers, small organic molecules that emit by fluorescence or by phosphorescence can serve as a light emitting material residing in active electronic layer 316. Unlike polymeric materials that are applied as solutions or suspensions, small-molecule light emitting materials are preferably deposited through evaporative, sublimation, or organic vapor phase deposition methods. Combinations of PLED materials and smaller organic molecules can also serve as active electronic layer. For example, a PLED may be chemically derivatized with a small organic molecule or simply mixed with a small organic molecule to form active electronic layer 316.

In addition to active electronic materials that emit light, active electronic layer 420 can include a material capable of charge transport. Charge transport materials include polymers or small molecules that can transport charge carriers. For example, organic materials such as polythiophene, derivatized polythiophene, oligomeric polythiophene, derivatized oligomeric polythiophene, pentacene, compositions including C60, and compositions including derivatized C60 may be used. Active electronic layer 420 may also include semiconductors, such as silicon or gallium arsenide.

Second Electrode (423)

In one embodiment, second electrode 423 functions as a cathode when an electric potential is applied across the first electrode 411 and second electrode 423. In this embodiment, when an electric potential is applied across the first electrode 411, which serves as the anode, and second electrode 423, which serves as the cathode, photons are released from active electronic layer 420 that pass through first electrode 411 and substrate 408.

While many materials, which can function as a cathode, are known to those of skill in the art, most preferably a composition that includes aluminum, indium, silver, gold, magnesium, calcium, and barium, or combinations thereof, or alloys thereof, is utilized.

Preferably, the thickness of second electrode 423 is from about 10 to about 1000 nanometers (nm), more preferably from about 50 to about 500 nm, and most preferably from about 100 to about 300 nm. While many methods are known to those of ordinary skill in the art by which the first electrode material may be deposited, vacuum deposition methods, such as physical vapor deposition (PVD) are preferred. Other layers (not shown) such as a barrier layer and getter layer may also be used to protect the electronic device. Such layers are well-known in the art and are not specifically discussed herein.

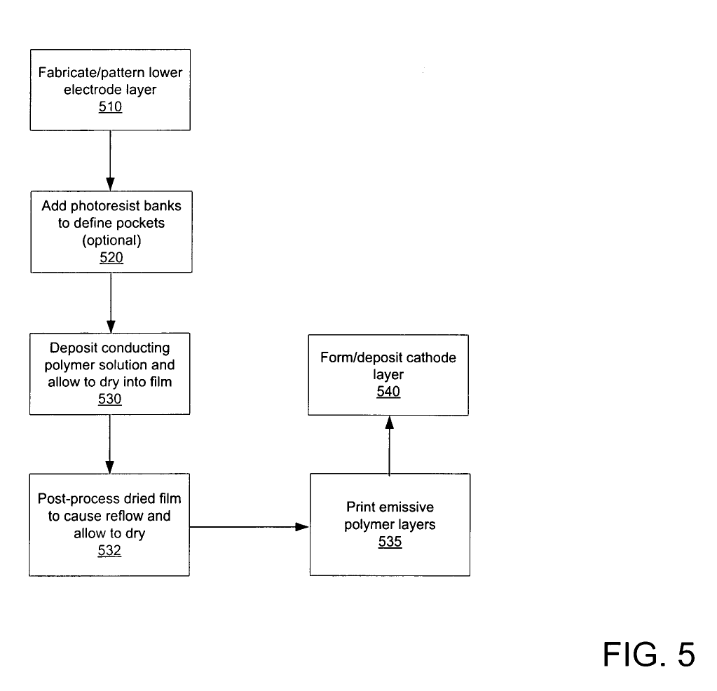

FIG. 5 shows a workflow of fabricating an organic electronic device in accordance with the invention. First, a lower electrode layer is fabricated/patterned over a substrate (step 510). The lower electrode layer preferably functions as an anode in the case of an OLED device. Typical anode materials include metals (e.g. aluminum, silver, copper, indium, tungsten, lead etc.); metal oxides; graphite; doped inorganic semiconductors (such as doped silicon, gallium arsenide and the like); and doped conducting polymers (such as polyaniline, polythiopene and the like).

For OLEDs, the lower electrode layer is usually thin enough so as to be semi-transparent and allow at least a fraction of light to transmit through (in bottom emitting OLEDs). As such, any thin-film deposition method may be used in the fabricating step 510. These include, but are not limited to, vacuum evaporation, sputtering, electron beam deposition, chemical vapor deposition, etching and other techniques known in the art and combinations thereof. The process also usually involves a baking or annealing step in a controlled atmosphere to optimize the conductivity and optical transmission of anode layer. Photolithography can then be used to define any pattern in the lower electrode layer.

The next step is to add a photo-resist bank structure such that pockets in the anode layer are defined (step 520). The photo-resist banks are fabricated by applying lithography techniques to a photo-resist material (or by using screen printing or flexo-graphic printing to deposit the bank material in the desired pattern). Photo-resist material is usually classified in two types, either positive or negative. Positive photo-resist is photo-resist which dissolves wherever exposed to light. Negative photo-resist is photo-resist which dissolves everywhere except where exposed to light. Either positive or negative photo-resist can be used as desired in forming the photo-resist banks. Photo-resist chemistry and processes such as lithography, baking, developing, etching and radiation exposure which can be used in patterning the photo-resist into banks are known to those skilled in the art. The addition of photo-resist banks in accordance with step 520 is merely optional, as it may be possible to perform inkjet printing without the use of photo-resist banks.

Next, the conducting polymer layer is fabricated by depositing a conducting polymer solution (step 530) over the patterned lower electrode layer. The conducting polymer layer is preferably applied using printing techniques such as ink-jet printing (screen printing, flexo-graphic printing) but may instead be spun-coat or otherwise non-selectively deposited, in the presence or absence of photo-resist banks. In this instance, the conducting polymer layer is printed within pockets defined by photo-resist banks. The conducting polymer layer is printed by depositing the organic solution into the pocket and allowing the deposited solution to dry into a film. The dried film then represents the conducting polymer layer. The conducting polymer layer is also referred to as a hole transport layer (“HTL”). The conducting polymer layer is used to improve, for example, the charge balance, the display stability, the turn-on voltage, the display brightness, the display efficiency, and the display lifetime. The conducting polymer layer is used to enhance the hole yield of the OLED relative to the potential applied across it and thus, aids in more energy-efficient injection of holes into the emissive polymer layer for recombination.

In accordance with the invention, according to step 532, the dried film is subjected to post-processing. In one embodiment of the invention, post-processing involves exposing the device under fabrication to a high humidity and high temperature environment for a specified period of time. The humidity and temperature and time of exposure should be sufficient enough to cause the dried film to reflow. Once reflow has been achieved, the substance which has undergone reflow is allowed to dry into the final HTL film. Among three conditions which can be adjusted in post-processing include the time of exposure, level of humidity (or vapor pressure) and the temperature. In general, the greater the temperature and/or humidity, the less the time of exposure. The optimum amount of time, humidity levels and temperature can be arrived at by experimentation or modeling or both. Different organic materials may have different post-processing conditions. The post-processing conditions should also be selected so as not to degrade other existing device structures or materials. The post-processing can be performed in a post-processing environment where individual variables such as temperature, time of exposure and humidity can be set, monitored and maintained, as desired.

Then according to step 535, the emissive polymer layers are printed. The emissive polymer layer is primarily responsible for the emission of light from the OLED and is thus a electroluminescent, semi-conducting and organic (organo-metallic) type material as discussed above. In inkjet printing, there may be a plurality of different emissive polymer substances. For instance, there may be red, green and blue emitting emissive polymers in the print head which are deposited depending upon the desired color to be emitted in a given pixel location which is defined by a pocket. The emitting polymer substances are deposited on the conducting polymer layer by the print head in the exact area defined by the pockets. The emissive polymer layer results from the drying of the substance deposited by the print head.

Both the conducting polymer layers and emissive polymer layers can be printed by depositing a liquid solution in between the photo-resist banks which define a pocket. This liquid solution may be any “fluid” or deformable mass capable of flowing under pressure at, below or above room temperature and may include solutions, inks, pastes, emulsions, dispersions and so on. The liquid may also contain or be supplemented by further substances which affect the viscosity, contact angle, thickening, affinity, drying, dilution and so on of the deposited drops.

After the emissive polymer layer is printed, the upper electrode layer is formed/deposited (step 540). In OLED devices, the upper electrode layer functions as a cathode (if the lower electrode layer is the anode). Cathode layer materials are discussed above. Insulating materials such as LiF, NaF, CsF and so on may also be used below the upper electrode layer to enhance injection by tunneling. The lower electrode layer is formed/deposited typically using vacuum evaporation or similar techniques and often using specially designed deposition devices. Often other steps such as the addition of masks and photo-resists may precede the cathode deposition step 540. However, these are not specifically enumerated as they do not relate specifically to the novel aspects of the invention. Other steps (not shown) like adding metal lines to connect the anode lines to power sources may also be included in the workflow. The workflow of FIG. 5 is not intended to be all-inclusive and is merely exemplary. For instance, after the OLED is fabricated it is often encapsulated to protect the layers from environmental damage or exposure. Such other processing steps are well-known in the art and are not a subject of the invention.

Alternatively, the after the conductive polymer layer is deposited on the substrate (step 530) but as it is drying, the substrate could be exposed to high temperature and/or high humidity. This would affect the film formation process such that the resulting film is substantially flat compared to a film formed when the conductive film is deposited in the absence of high temperature and/or high humidity.

The post-processing of an organic film can serve to provide a flat and uniform drying profile of any organic solution which is deposited thereon. It can also be used to reduce defects such as pinholes and improve adhesion between different materials. The invention is not thus limited to any one type of deposited solution or device.

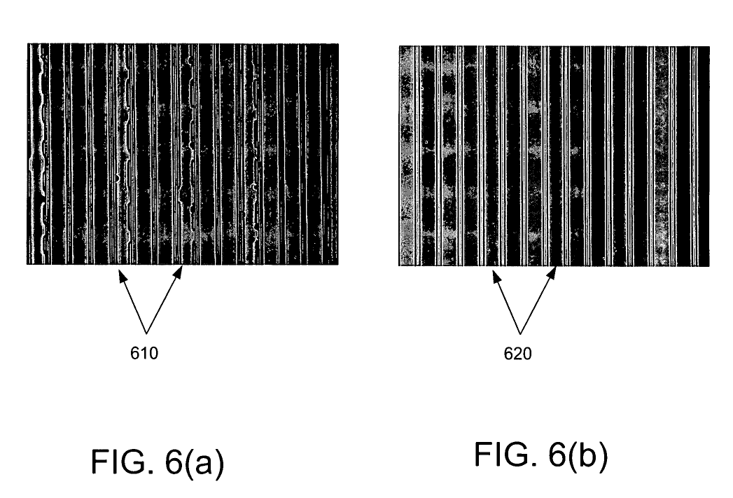

FIGS. 6(a) and 6(b) illustrate improved coverage of the substrate that leads to a reduction of pinhole defects and incomplete filling of the material in the desired region as well as improved contact/adhesion of the film to the features on the substrate when utilizing one or more embodiments of the invention. FIG. 6(a) shows the results of a conventional printing process depositing organic material on a substrate between photo-resist lines. The drop pitch of the deposition is small so that drops can coalesce together and form lines 610 of film as shown. The lines 610 of organic material show defects however in the form of irregularities called “pinholes”. The top view shown in FIG. 6(a) illustrates these pin-holes as discontinuities and small areas where the film is not present. When other layers are stacked over this layer of film, the pin-holes can cause unwanted conducting paths resulting in high leakage currents which can degrade device performance.

However, when the same deposited material is subjected to reflow in accordance with the invention, the occurrence of pin-hole defects and incomplete filling of the lines 610 is reduced. This is illustrated in FIG. 6(b). The lines 620 of organic film show little or no discontinuities and therefore, fewer pinholes. The redistribution of material comprising the film when the film undergoes reflow enables the gaps or discontinuities in the films 610 to be corrected. The redistribution also leads to improved contact/adhesion to the other features on the substrate.

While the embodiments of the invention are illustrated in which it is primarily incorporated within an OLED display, almost any type of electronic device that uses dried film layers may be potential applications for these embodiments. In particular, present invention may also be utilized in a solar cell, a transistor, a phototransistor, a laser, a photo-detector, or an opto-coupler. It can also be used in biological applications such as bio-sensors or chemical applications such as applications in combinatorial synthesis etc. The OLED display described earlier can be used within displays in applications such as, for example, computer displays, information displays in vehicles, television monitors, telephones, printers, and illuminated signs.

1. A method of fabricating an organic electronic device, said method comprising:
depositing an organic material upon an existing deposition surface;
allowing said organic material to dry into an organic film;
post-processing said organic film under a post-processing environment with conditions such that said organic film undergoes reflow; and
allowing said film which has undergone reflow to dry into an enhanced organic layer film, said enhanced organic film comprising a substantially flat and uniform profile.

2. A method according to claim 1 wherein said organic material is deposited by techniques such as inkjet printing, flexographic printing or screen printing.

3. A method according to claim 1 wherein said organic electronic device is an organic light emitting diode (OLED) display.

4. A method according to claim 3 wherein said existing deposition surface is a lower electrode layer.

5. A method according to claim 4 wherein said organic material is a conducting polymer solution.

6. A method according to claim 5 further comprising:
fabricating an emissive layer above said enhanced organic film, said emissive layer emitting light upon charge recombination.

7. A method according to claim 6 further comprising:
fabricating a photo-resist layer upon said lower electrode layer, said photo-resist layer patterned into a plurality of lines to define deposition regions upon said lower electrode layer.

8. A method according to claim 1 wherein said device is an organic transistor.

9. A method according to claim 1 wherein said device is an organic solar cell.

10. A method according to claim 5 wherein said conducting polymer solution is a PEDOT solution.

11. A method according to claim 1 wherein said conditions includes at least one of high humidity and high temperature.

12. A method according to claim 11 wherein said conditions include time of exposure.

13. A method according to claim 11 wherein said conditions includes a temperature of 85C. and a relative humidity of 95%.

14. A method according to claim 1 wherein said environment includes high vapor pressure of solvents that cause the material in the film to reflow.

15. A method according to claim 1 wherein said enhanced organic film exhibits a reduced number of pinhole defects.

16. A method according to claim 1 wherein said enhanced organic film exhibits an improved coverage of the substrate.

17. A method according to claim 1 wherein said enhanced organic film exhibits better contact with other features of said organic electronic device.

18. A method of fabricating an organic electronic device, said method comprising:
depositing an organic material upon an existing deposition surface;
allowing said organic material to dry;
during said drying subjecting said organic material to an environment with conditions such that said organic material undergoes reflow, said material after completing reflow drying into an enhanced organic film comprising a substantially flat and uniform profile.
